(19) United States
(12) Patent Application Publication
(10) Pub. No.: US 2026/0038312 A1
(43) Pub. Date: Feb. 5, 2026

(54) METHOD FOR MONITORING STATES, IN PARTICULAR FOR DETECTING UNWANTED STATES, IN A VEHICLE, CONTROL DEVICE, AND VEHICLE

(71) Applicant: Volkswagen Aktiengesellschaft, Wolfsburg (DE)

(72) Inventor: Dominic HUSCHKE, Jena (DE)

(73) Assignee: Volkswagen Aktiengesellschaft, Wolfsburg (DE)

(21) Appl. No.: 19/350,909

(22) Filed: Oct. 6, 2025

Related U.S. Application Data
(63) Continuation of application No. PCT/EP2024/054684, filed on Feb. 23, 2024.

(30) Foreign Application Priority Data
Apr. 4, 2023 (DE) 10 2023 203 127.2

(51) Int. Cl. G07C 5/08; B60L 58/10; G01R 31/00; H01M 10/48; H01M 50/249

(52) U.S. Cl. CPC G07C 5/0808; B60L 58/10; G01R 31/007; G07C 5/0816; H01M 10/486; H01M 50/249; H01M 2220/20

(57) ABSTRACT

A method for monitoring states, in particular for detecting unwanted states, in a vehicle. A state detector is provided at a semiconductor switch for at least one functionally essential vehicle component of the vehicle. At least one operating parameter of the at least one functionally essential component is monitored with the aid of the semiconductor switch. The state of the vehicle is evaluated depending on the monitoring.

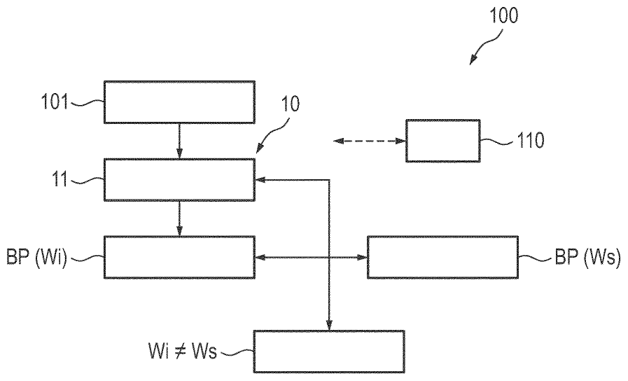

This nonprovisional application is a continuation of International Application No. PCT/EP2024/054684, which was filed on Feb. 23, 2024, and which claims priority to German Patent Application No. 10 2023 203 127.2, which was filed in Germany on Apr. 4, 2023, and which are both herein incorporated by reference.

### BACKGROUND OF THE INVENTION

### Field of the Invention

The invention relates to a method for monitoring states, in particular for detecting unwanted states, in a vehicle. Further, the invention relates to a corresponding computer program product for carrying out a corresponding method. Furthermore, the invention relates to a corresponding control device for carrying out a corresponding method. Moreover, the invention relates to a corresponding vehicle with a corresponding control device.

### Description of the Background Art

Monitoring methods for vehicles are generally known. In most cases, control units are used for monitoring. To that end, the control units must be activated either permanently or regularly. As a result, the control units consume energy.

### SUMMARY OF THE INVENTION

It is therefore an object of the present invention to at least partially overcome at least one of the disadvantages described above. In particular, it is an object of the invention to provide an improved method for monitoring states, in particular for detecting unwanted states, in a vehicle. Preferably, it is an object of the invention to provide an improved method for monitoring states, in particular for detecting unwanted states, in a vehicle, which method can be carried out with little effort and little energy, which uses existing resources in the vehicle in an improved manner, which enables reliable detection of unwanted states, which enables a comprehensible and intuitive interaction with a user of the vehicle, and which increases customer comfort and confidence in the vehicle. Further, it is the object of the invention to provide a corresponding computer program product for carrying out a corresponding method. Furthermore, it is the object of the invention to provide a corresponding control device for carrying out a corresponding method. Moreover, it is the object of the invention to enable a corresponding vehicle with a corresponding control device.

The foregoing object is achieved by a method for monitoring states, in particular for detecting unwanted states, in a vehicle with the features of the independent method claim. Further, the foregoing object is achieved by a corresponding computer program product for carrying out a corresponding method with the features of the independent product claim. Furthermore, the foregoing object is achieved by a corresponding control device for carrying out a corresponding method with the features of the independent device claim. Moreover, the foregoing object is achieved by a corresponding vehicle with a corresponding control device with the features of the parallel device claim. Features disclosed with respect to different aspects of the invention may be combined without going beyond the scope of the present disclosure.

The invention provides a method for monitoring states, in particular for detecting unwanted states, in a vehicle, comprising: providing a state detector at a semiconductor switch for at least one functionally essential vehicle component of the vehicle, monitoring at least one operating parameter of the at least one functionally essential component with the aid of the semiconductor switch, and evaluating the state of the vehicle depending on the monitoring.

The invention recognizes that semiconductor switches (often referred to as electronic fuses) are increasingly being used in vehicles to protect electrical consumers. The invention also recognizes that semiconductor switches provide functional advantages in terms of sensor technology and communication.

In addition to the actual safety function, semiconductor switches offer a wide range of other functionalities. This includes expanded diagnostic options, which include, for example, the measurement of currents, voltages, and temperatures. Furthermore, the possibility for semiconductor switches to communicate, for example, via a bus or even wirelessly is worth mentioning. Moreover, it is advantageous in the case of semiconductor switches that they can be programmed for different applications, for example, via software, e.g., via over-the-air interfaces. The invention thus recognizes that semiconductor switches are in principle always “responsive,” even when they are partly in sleep mode.

Detection of unwanted states of a motor vehicle by intelligent semiconductor switches is proposed within the scope of the method. The current state of the vehicle can be detected in an advantageous way using a state detector. The state detector can advantageously be realized with the aid of intelligent semiconductor switches. The state detector can, for example, be realized as a software and/or hardware module in the semiconductor switch. The detection of the state now occurs with the aid of the expanded diagnostic options of the intelligent semiconductor switches by measuring the current, voltage, and/or temperature. Thus, for example, the detection of the state of individual consumers, such as, for example, the infotainment system, is possible by measuring the current. Furthermore, by measuring the current of consumers, such as, for example, the cooling fan, conclusions can be drawn about the vehicle's state of motion. By comparing the actual value now determined with a target value specified, for example, by a vehicle owner, it can be detected further whether the vehicle is in the state desired by the vehicle owner. The target value can be defined, for example, at the start of vehicle use, e.g., as a default value. It is conceivable that when the vehicle is locked, all consumers should be deactivated and/or the vehicle should not move. If there is a deviation between the actual and target values, the vehicle owner can be informed of this, for example, via a text message or the like, because in certain cases theft of the vehicle can be assumed, for example.

An improved method for monitoring states, in particular for detecting unwanted states, in a vehicle can thus be provided with the aid of the invention, which method can be carried out with little effort and little energy, which uses existing resources in the vehicle, in particular semiconductor switches, in an improved manner, which enables reliable detection of unwanted states, which enables a comprehensible and intuitive interaction with a user of the vehicle, and which significantly increases customer comfort and confidence in the vehicle.

Further, it can be provided that the at least one operating parameter (BP) comprises at least one of the following parameters: current, voltage, and/or temperature.

In this way, it can be easily and reliably detected whether the corresponding functionally essential vehicle component is being operated or not. Further diagnostics of the operation of the functionally essential vehicle components are also enabled thereby. In this way, a conclusion can be drawn about the state of the vehicle as such.

Furthermore, it can be provided that a state of the at least one functionally essential component is taken into account in the evaluation of the state of the vehicle. In this way, it can be detected using simple measures and without great computing effort whether the at least one functionally essential component is active and/or how it is operated. This can be used to evaluate the state of the vehicle in an improved way.

Furthermore, it can be provided that a status detector is provided in each case at a corresponding semiconductor switch for at least one of the following functionally essential vehicle components of the vehicle: a battery, in particular an on-board power supply battery, for example, a 12V battery or a 48V battery, a high-voltage battery, in particular a traction battery, a display device, for example, a display, an instrument cluster, and/or a head-up display, an infotainment system, a braking system, in particular a brake-by-wire system, a steering system, in particular a steer-by-wire system, a cooling fan, an electric motor, a control unit, a communications unit, and/or an electrical consumer.

In this way, the resources in the vehicle can be utilized in an improved way for expanded status detection. The state of the vehicle can therefore be evaluated precisely and reliably.

In addition, it can be provided that the states of a plurality of functionally essential components are taken into account when evaluating the state of the vehicle. In this way, an expanded vehicle state detection can be utilized in an improved manner.

It can also be provided that, when evaluating the state of the vehicle, the at least one operating parameter is compared with at least one target value and/or target value range. In this way, detection of the state in a vehicle can be carried out easily and without a great deal of computing effort.

Further, it can be provided that the target value and/or the target value range are determined accordingly for different operating situations of the vehicle. The operating situations can be as follows, for example: vehicle is parked (idle mode), as many of the vehicle's electrical consumers as possible should be switched off; vehicle is being charged (charging mode), if possible, all of the vehicle's electrical consumers should be switched off and only the charger should be operated; vehicle is driving (normal mode), etc. In this way, suitable parameter sets for different operating parameters can be provided specifically for different vehicle operating situations.

Furthermore, it can be provided that presettings for the target value and/or the target value range are determined automatically, for example, by a control device of the vehicle (or a control device of a workstation). In this way, suitable parameter sets for different operating parameters can be preset automatically. This can be referred to as default settings or factory settings.

Moreover, it can be provided that settings for the target value and/or the target value range are determined and/or adjusted dynamically (for example, periodically and/or event-specifically and/or as required), for example, by a user of the vehicle. In this way, an advantageous interaction with the user can be created, which increases customer comfort and confidence in the vehicle.

Additionally, it can be provided that if, when evaluating the state of the vehicle, it is detected that an actual value of the at least one operating parameter deviates from a target value and/or target value range, at least one of the following steps is carried out: evaluating a state of the vehicle, and preferably providing a classification, for example, idle mode-OK, or idle mode-attention consumer active and risk of theft, etc.; providing a message, in particular comprising the actual value of the at least one operating parameter and/or a classification of an unwanted state of the vehicle, to a user of the vehicle and/or to a monitoring device, for example, a central monitoring device; preferably via wireless communication, preferably with the aid of the semiconductor switch, the semiconductor switch can report unusual actual values to a control unit of the vehicle, which can then activate the communications unit of the vehicle for the purpose of reporting; outputting a warning signal, for example, in the form of an alarm; and initiating a protective measure, for example, automatic turning off of the vehicle.

In this way, safety during operation of the vehicle can be increased.

The invention provides a computer program product comprising instructions which, when the computer program is executed by a computer, cause the computer to carry out a method which may proceed as described above. In so doing, the same advantages described above can be achieved.

The invention provides a corresponding control device for monitoring states, in particular for detecting unwanted states, in a vehicle, comprising a memory device and a computing device, wherein a code is stored in the memory device and wherein, when the code is executed by the computing device, a method is carried out which can proceed as described above. In so doing, the same advantages described above can be achieved.

The invention provides a vehicle having a corresponding control device. The same advantages can be achieved which were described above in connection with the method.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWING

The present invention will become more fully understood from the detailed description given hereinbelow and the accompanying drawing which are given by way of illustration only, and thus, are not limitive of the present invention, and wherein the sole figure shows a schematic representation of a sequence of a method for detecting unwanted states in a vehicle.

### DETAILED DESCRIPTION

The figure serves to explain a method which was developed for monitoring states, in particular for detecting unwanted states, in a vehicle 100: providing a state detector 11 at a semiconductor switch 10 for at least one functionally essential vehicle component 101 of the vehicle 100; monitoring at least one operating parameter BP of the at least one functionally essential component 101 with the aid of semiconductor switch 10; and evaluating the state of vehicle 100 depending on the monitoring.

With the aid of the invention, semiconductor switches 10 (often also referred to as electronic fuses), which are increasingly being used in vehicles to protect electrical consumers, can be used advantageously for monitoring states, in particular for detecting unwanted states, in a vehicle 100. The invention advantageously utilizes the functional advantages of semiconductor switches 10 in terms of sensor technology and communication.

The invention recognizes that semiconductor switches 10 offer a wide range of other functionalities in addition to the actual safety function, such as, e.g., diagnostic options, which include, for example, the measurement of currents, voltages, and temperatures, communication options, for example, via a BUS or even wirelessly, as well as various application options, for example, via software, e.g., via over-the-air interfaces. The invention thus recognizes that semiconductor switches 10 are in principle always “responsive,” even when they are partly in idle mode.

It is now proposed to realize a state detector 11 with the aid of such intelligent semiconductor switches 10 in order to determine the current state of vehicle 100. State detector 11 can, for example, be implemented as a software and/or hardware module in semiconductor switch 10. The detection of the state now occurs with the aid of the expanded diagnostic options of intelligent semiconductor switches 10, in particular by measuring the operating parameters BP of current, voltage, and/or temperature. Thus, for example, the detection of the state of individual consumers, such as, for example, the infotainment system, is possible by measuring the current. Furthermore, by measuring the current of consumers, such as, for example, the cooling fan, conclusions about the movement state of vehicle 100 can be drawn. By comparing the actual value now determined with a target value specified, for example, by a user of vehicle 100, it can be detected furthermore whether vehicle 100 is in the state desired by the user. The target value Ws can be defined, for example, at the start of vehicle use, e.g., as a default value. It is conceivable here that when vehicle 100 is locked, all electrical consumers should be deactivated and/or vehicle 100 should not move. If a deviation between the actual value Wi and the target value Ws is detected, the user can be informed of this, for example, via a text message or the like, because in certain cases theft of vehicle 100 can be assumed, for example.

Advantageously, a state of the at least one functionally essential component 101 can be taken into account when evaluating the state of vehicle 100.

The following functionally essential vehicle components 101 of vehicle 100 are conceivable, which can have a semiconductor switch 10: a battery, in particular an on-board power supply battery, for example, a 12V battery or a 48V battery, a high-voltage battery, in particular a traction battery, a display device, for example, a display, an instrument cluster, and/or a head-up display, an infotainment system, a braking system, in particular a brake-by-wire system, a steering system, in particular a steer-by-wire system, a cooling fan, an electric motor, a control unit, a communications unit, and/or an electrical consumer.

When evaluating the state of vehicle 100, states of a number of functionally essential components 101 can also be taken into account.

As indicated in the figure, the at least one operating parameter BP can be compared with at least one target value Ws and/or target value range when evaluating the state of vehicle 100.

In so doing, the target value Ws and/or the target value range can be determined individually for different operating situations of vehicle 100.

Presettings for the target value Ws and/or the target value range can, for example, be determined automatically, for example, by a control device 110 of vehicle 100.

Settings for the target value Ws and/or the target value range can in turn be determined and/or adapted dynamically, for example, by a user of vehicle 100.

Further steps can be provided in the method, such as, e.g.: evaluating a state of vehicle 100 and, if necessary, providing a classification of a state of vehicle 100; providing a message, in particular comprising the actual value Wi of the at least one operating parameter BP and/or a classification of an unwanted state of vehicle 100, to a user of vehicle 100 and/or to a monitoring device, for example, a central monitoring device; preferably via wireless communication, preferably with the aid of semiconductor switch 10; outputting a warning signal; and initiating a protective measure, for example, automatic turning off of vehicle 100.

Furthermore, the invention provides a corresponding computer program product and a corresponding control device 110 for carrying out the method.

Moreover, the invention provides a vehicle 100 with a corresponding control device 110.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for monitoring states, in particular for detecting unwanted states, in a vehicle, the method comprising:
providing a state detector at a semiconductor switch for at least one functionally essential vehicle component of the vehicle;
monitoring at least one operating parameter of the at least one functionally essential component via the semiconductor switch; and
evaluating a state of the vehicle depending on the monitoring.

2. The method according to claim 1, wherein the at least one operating parameter comprises at least one of the following parameters:
current;
voltage; and/or
temperature.

3. The method according to claim 1, wherein a state of the at least one functionally essential component is taken into account when evaluating the state of the vehicle.

4. The method according to claim 1, wherein a state detector is provided at a corresponding semiconductor switch for at least one of the following functionally essential vehicle components of the vehicle:
a battery, in particular an on-board power supply battery, for example, a 12V battery or a 48V battery;
a high-voltage battery, in particular a traction battery;
a display device, for example, a display, an instrument cluster, and/or a head-up display;
an infotainment system;
a braking system, in particular a brake-by-wire system;
a steering system, in particular a steer-by-wire system;
a cooling fan;
an electric motor;
a control unit;
a communications unit; and/or
an electrical consumer.

5. The method according to claim 1, wherein states of a plurality of functionally essential components are taken into account when evaluating the state of the vehicle.

6. The method according to claim 1, wherein the at least one operating parameter is compared with at least one target value and/or target value range when evaluating the state of the vehicle.

7. The method according to claim 1, wherein the target value and/or the target value range are determined accordingly for different operating situations of the vehicle, wherein presettings for the target value and/or the target value range are determined automatically by a control device of the vehicle, and wherein settings for the target value and/or the target value range are determined and/or adapted dynamically by a user of the vehicle.

8. The method according to claim 1, wherein, if, when evaluating the state of the vehicle, it is detected that an actual value of the at least one operating parameter deviates from a target value and/or target value range, at least one of the following steps is carried out:
evaluating a state of the vehicle;
providing a message comprising the actual value of the at least one operating parameter and/or a classification of an unwanted state of the vehicle to a user of the vehicle and/or to a monitoring device or a central monitoring device via wireless communication or with the aid of the semiconductor switch;
outputting a warning signal; and/or
initiating a protective measure, for example, automatic turning off of the vehicle.

9. A computer program product comprising instructions which, when the computer program is executed by a computer, cause the computer to carry out a method according to claim 1.

10. A control device for monitoring states, in particular for detecting unwanted states, in a vehicle, the control device comprising:
a memory; and
a processor,
wherein a code is stored in the memory, and
wherein, when the code is executed by the computing device, the method according to claim 1 is carried out.

11. A vehicle comprising the control device according to the claim 10.
